(19) United States
(12) Patent Application Publication
(10) Pub. No.: US 2007/0274138 A1
(43) Pub. Date: Nov. 29, 2007

(54) REFERENCE VOLTAGE GENERATING CIRCUIT

(75) Inventors: Ryu Ogiwara, Yokohama-shi (JP); Daisaburo Takashima, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/684,183

(22) Filed: Mar. 9, 2007

(30) Foreign Application Priority Data
Apr. 4, 2006 (JP) 2006-103048

(51) Int. Cl. G11C 5/14

(52) U.S. Cl. 365/189.09

(57) ABSTRACT

In this reference voltage generating circuit, the first current generating circuit generates the first constant current irrespective of the power supply voltage, when temperature is constant. When temperature changes, the magnitude of the first current changes according to the change. The second current generating circuit generates a second current depending on the power supply voltage. An output circuit outputs the output voltage. It has a resistor element for flowing the third current as an addition of the first current and the second current. An output voltage is output by the voltage drop of this resistor element.

### CROSS REFERENCE TO RELATED APPLICATIONS

This application is based on and claims the benefit of priority from prior Japanese Patent Application No. 2006-103048, filed on April 4, the entire contents of which are incorporated herein by reference.

### BACKGROUND OF THE INVENTION

1. Field of the Invention

The present invention relates to a reference voltage generating circuit generating a reference voltage used in a semiconductor memory device or the like.

2. Description of the Related Art

In a field of a ferroelectric random-access memory (FeRAM), developments of a 1T1C type memory cell suitable for realization of large-scaled memory capacity are under way. An ferroelectric random-access memory of this type stores 1 bit data using one transistor and one capacitor. For this reason, a read-out potential of a memory cell and reference potential needs to be compared to perform data reading. The read-out potential of a memory cell is read to a bit line, and the reference potential is read to the complementary bit line that makes a pair with the bit line. The difference in voltage is amplified and compared in a sense amplifier.

For generating this reference potential, a dummy cell that generates the reference potential is prepared apart from the usual memory cell for storing data. The dummy cell comprises a selection transistor and a dummy capacitor.

A Voltage VDC is applied between both of the electrodes of the dummy capacitor. As described in the JP2005-339724A, it is pointed out that this potential VDC needs to have a positive temperature dependency, and to be dependent on an array voltage VAA (a operation voltage of a sense amplifier). A technology for giving both a temperature dependency and an array voltage dependency is disclosed in JP2005-339724A.

However, with the technology of JP2005-339724A, the temperature dependency and the array voltage dependency cannot be adjusted independently. If it is possible to control both the dependency toward the array voltage VAA and the dependency toward temperature T independently from the other, the dummy plate voltage VDC can be controlled to a proper value at all times thereby increasing a sense margin more.

### SUMMARY OF THE INVENTION

The reference voltage generating circuit according to one aspect of the present invention comprises: a first current generating circuit generating a first current that is constant irrespective of a power supply voltage when temperature is constant, while the magnitude of the first current changes, when temperature changes, in accordance with the change of temperature; a second current generating circuit generating a second current depending on the power supply voltage;

an output circuit including a resistor element flowing a third current generated by adding the first current and the second current to output an output voltage produced by the voltage drop of the resistor element.

### BRIEF DESCRIPTION OF THE DRAWINGS

FIG. 1 is a circuit diagram showing the composition of the reference voltage generating circuit 1 according to the first embodiment of the present invention.

FIG. 2 shows an example of the composition for making the dependency of the output voltage VDC toward temperature T in the reference voltage generating circuit 1 of FIG. 1.

FIG. 3 shows an example of the composition for increasing or decreasing the dependency of the output voltage VDC toward temperature T in the reference voltage generating circuit 1 of FIG. 1.

FIG. 4 shows an example of the composition for increasing or decreasing the dependency of the output voltage VDC toward the operation voltage VAA in the reference voltage generating circuit 1 of FIG. 1.

FIG. 5 shows an example of the composition for increasing or decreasing the dependency of the output voltage VDC toward the operation voltage VAA in the reference voltage generating circuit 1 of FIG. 1.

FIG. 6 is a circuit diagram showing the composition of the reference voltage generating circuit 1′ according to the second embodiment of the present invention.

FIG. 7 shows an example of a cell array unit CA of a ferroelectric random-access memory with 1T1C type memory cells, and a sense amplifier SA.

### DETAILED DESCRIPTION OF THE EMBODIMENTS

Hereinafter, a reference voltage generating circuit according to embodiments of the present invention is explained in detail with reference to drawings. The following explanation explains the case where the reference voltage generating circuit of this embodiment is applied to a ferroelectric random-access memory as an example. However, it is needless to say that the present invention is not limited to this, but may be applied to other semiconductor integrated circuits having the same object.

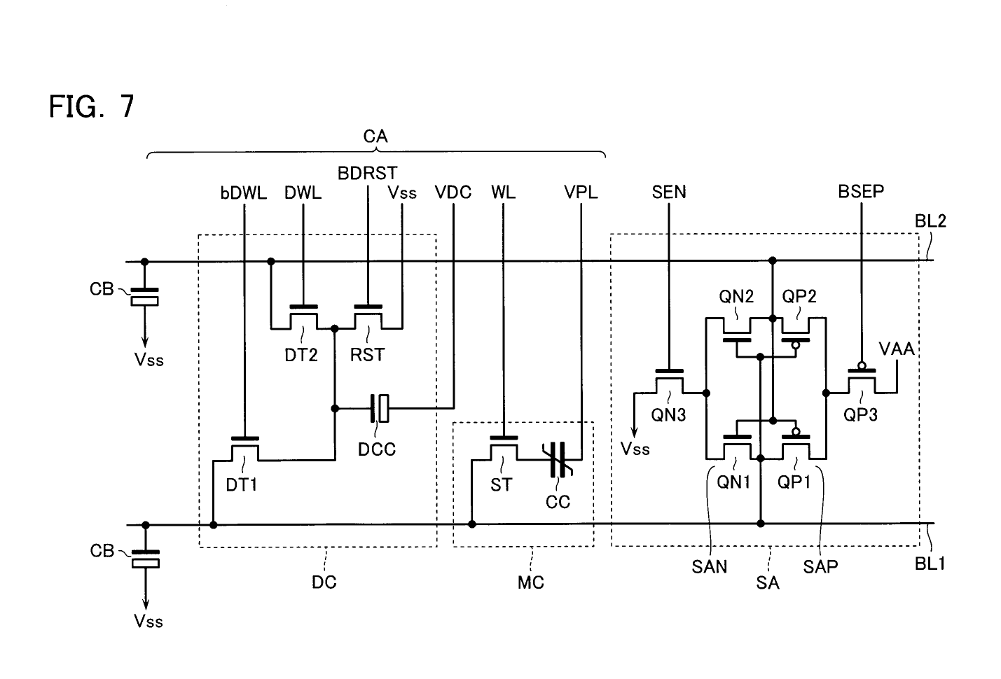

The example of a cell array unit CA of a ferroelectric random-access memory having a DRAM type memory cell, and a sense amplifier SA is shown in FIG. 7. The memory cell MC and the dummy cell DC are formed in the cell array unit CA.

A memory cell MC is formed by serial connection of a selection transistor ST and a ferroelectric capacitor (cell capacitor) CC. One end of the selection transistor ST is connected to a bit line BL1, and one end of the ferroelectric capacitor CC is provided with a plate voltage VPL. Moreover, the word line WL is connected to the gate of the selection transistor ST.

On the other hand, the dummy cell DC is composed of a selection transistor DT1, DT2, a dummy capacitor DCC, and a reset transistor RST. The dummy capacitor DCC and the selection transistor DT1 are serially connected between the dummy plate voltage VDC and the bit line BL1. The dummy capacitor DCC and the selection transistor DT2 is serially connected between the dummy plate voltage VDC and the bit line BL2.

The dummy word line DWL and bDWL are connected to a gate of the selection transistor DT1 and DT2, respectively. Moreover, the reset transistor RST has one end connected to a connecting node between the dummy capacitor DCC and the selection transistor DT1 or DT2. Moreover, the reset transistor RST has other end connected to the ground potential Vss, and a control signal BDRST is given to its gate.

On the other hand, the sense amplifier SA is formed between the bit lines BL1 and BL2. This sense amplifier SA has a p-type sense amplifier SAP composed two p-type MOS transistors QP1 and QP2. Furthermore, this sense amplifier SA has an n-type sense amplifier SAN composed of two n-type MOS transistors QN1 and QN2. The sense amplifier SA is given the operation voltage VAA by a transistor QP3. ON/OFF control of the sense amplifier SA is carried out by the control signal BSEP and the control signal SEN, which are given to the gate of transistors QP3 and QP4, respectively.

The plate line voltage VPL is given to one end of the ferroelectric capacitor CC of the memory cell MC in such a ferroelectric memory. Moreover, the dummy plate voltage VDC is given to one end of the dummy capacitor DCC of the dummy cell DC. It is necessary that the plate line voltage VPL and the dummy plate voltage VDC have a certain relation to the operation voltage VAA of the sense amplifier.

It is thought at present that the plate voltage VPL should be equal to the operation voltage VAA of the sense amplifier. Moreover, the dummy plate voltage VDC has a certain temperature dependency according to the temperature dependency of the read-out potential of the memory cell MC. At the same time, the experiment has proved that the dummy plate line voltage VDC has a positive dependency toward the operation voltage VAA of a sense amplifier.

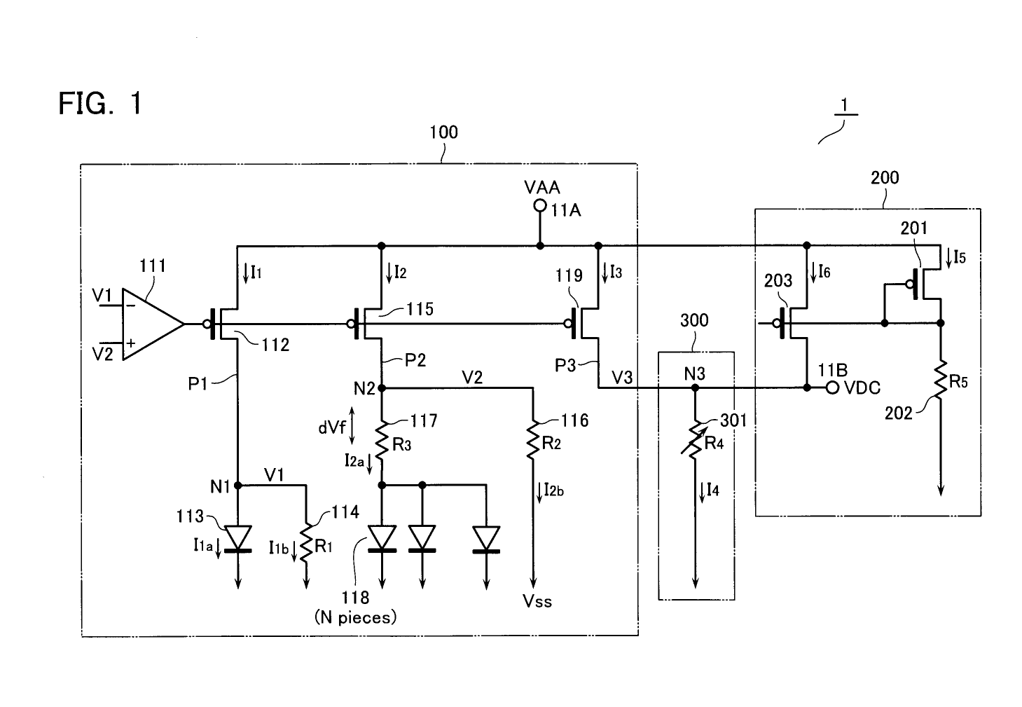

Therefore, the reference voltage generating circuit of this embodiment inputs from an input terminal (11A) the operation voltage VAA of the sense amplifier as a power supply voltage, and generates the dummy plate voltage VDC at an output terminal (11B). Moreover, the dummy plate voltage VDC is generated to have a temperature dependency by a circuit (100) mentioned later. Thereby, this embodiment can control independently the dependency of the dummy plate voltage VDC toward the voltage VAA, and the dependency toward temperature T. Hereafter, the composition of the reference voltage generating circuit 1 of this embodiment is explained with reference to FIG. 1.

This reference voltage generating circuit 1 is generally composed of a first current generating circuit 100, a second current generating circuit 200, and an output circuit 300.

The first current generating circuit 100, generates a constant output current (I3) irrespective of the power supply voltage (the operation voltage VAA), when temperature T is constant.

On the other hand, when temperature T changes, the reference voltage generating circuit 1 is configured so that the magnitude of the output current (I3) may change according to the change of the temperature T.

Moreover, the second current generating circuit 200 is configured to generate an output current (I6) that changes depending on the operation voltage VAA as a power supply voltage. Note that although it is not necessary in this embodiment to use the operation voltage VAA as a power supply voltage of the first current generating circuit 100. However, in this embodiment, in order for simplification of a circuit, the voltage VAA is used as a power supply voltage.

Moreover, the output circuit 300 is configured to output an output voltage VDC, i.e., the dummy plate voltage VDC. This voltage VDC is produced by a voltage drop based on a current (I4). This current I4 is generated by adding each of the output currents (I3, I6) in the first current generating circuit 100 and the second current generating circuit 200, respectively.

An example of the composition of the first current generating circuit 100 is explained with reference to FIG. 1.

This first current generating circuit 100 is equipped with an operational amplifier 111. Moreover, it comprises an input terminal 11A for inputting the operation voltage VAA as a power supply voltage. A first current path P1 is formed between this input terminal 11A and the terminal of the ground potential Vss.

In the first current path P1, a p-type MOS transistor 112 (the first transistor) and a diode 113 (the first diode) is a serially connected. Furthermore, a resistor 114 (a resistance value of R1, a first resistor element) is provided connected in parallel with the diode 113.

Moreover, the second current path P2 is formed in parallel with this first current path P1. In the second current path P2, a p-type MOS transistor 115 (a second transistor) and a resistor 116 (a resistance value of R2, a second resistor element) are serially connected. Furthermore, a resistor 117 (a resistance value of R3, a third resistor element) and N pieces of diodes 118 (a second diode) connected in parallel with one another, are serially connected. The resistor 117 and the diodes 118 are connected in parallel with the resistor 116.

Similarly, the third current path P3 is connected in parallel with the first current path P1 and the second current path P2. This third current path P3 is composed of a p-type MOS transistor 119 (a third transistor) and a resistor 301 (a resistance value of R4).

The resistor 301 makes up a part of the output circuit 300. In addition, the resistor 301 is a variable resistor for adjustment of the absolute value of the output voltage VDC.

The p-type MOS transistors 112, 115, and 119 are transistors of the same size. Their gates are commonly connected to the output terminal of the operational amplifier 111 to form a current mirror circuit. Thereby, the current I1 I2, and I3 (I1=I2=I3) having the same magnitude flow in the first, second, and third current path P1-P3 so that the voltage V1 of the node N1 between the p-type MOS transistor 112 and the diode 113 is equal to the voltage V2 of the node N2 between the p-type MOS transistor 115 and the resistor 116.

Moreover, the voltage V1 of the node N1 is input to the inverting input terminal of the operational amplifier 111, and the voltage V2 of the node N2 is input to the non-inverting input terminal of the operational amplifier 111.

Here, a current flowing in the diode 113 is defined as I1a, a current flowing in the resistor 114 as 11b (I1=I1a+I1b).

### A current flowing in the resistor 117 is defined as I2a, and a current flowing in the resistor 116 as I2b (I2=I2a+I2b) When R1=R2 is set, the followings may be represented.

I1a=I2a

I1b=I2b

V1=Vf1

V2=Vf2+dVf

DVf=Vf1−Vf2 [Expression 1],

Where Vf1 and Vf2 denotes the forward direction voltage of the diodes 113 and 118. Since DVf denotes a voltage between the both ends of the resistor 117, the followings may be represented.

I2a=dVf/R3

I2b=Vf1/R2 [Expression 2]

Therefore, the output current I2 and I3 may be expressed as follows.

I2=I3=I2a+I2b=Vf1/R2+dVf/R3 [Expression 3]

Suppose that only the current I3 flows in the resistor 301 of the output circuit 300, the output voltage VDC (100) from the output circuit 300 may be expressed as follows.

VDC(100)=R4x (Vf1/R2+dVf/R3)=R4x(Vf1/R2+VT/R3×logN) [Expression 4]

When temperature T is constant, this current I3 and the output voltage VDC (100) is constant irrespective of the power supply voltage (the operation voltage VAA).

Also when temperature T changes, Vf1 has a temperature characteristic of −2 [mV/° C.] while VT has a temperature characteristic of +0.086 [mV/° C.]. Therefore, by choosing a resistance value of R2 and R3 suitably, the current I3 and the output voltage VDC (100) may be made constant irrespective of temperature T (further, irrespective of the magnitude of the power supply voltage (operation voltage VAA)). It is also possible to make the temperature dependency either positive or negative.

When generating the dummy plate voltage VDC of the ferroelectric memory as shown in FIG. 7, it is suitable to choose resistance values of R2 and R3 so that VDC may have positive temperature characteristic (the voltage VDC becomes large as the temperature elevates).

In this way, the first current generating circuit 100 may suitably adjust its internal resistor. Thereby, it generates the output current (I3) that is constant irrespective of the power supply voltage (the operation voltage VAA) when temperature T is constant. In contrast, when temperature T changes, the magnitude of the output current (I3) may be changed according to the change.

On the other hand, the second current generating circuit 200 is equipped with a diode-connected p-type MOS transistor 201, a resistor 202 (a resistance value of R5), and a p-type MOS transistor 203. The sizes of the p-type MOS transistors 201 and 203 are made equal. Their gates are commonly connected while the operation voltage VAA is given to their sources to form a current mirror circuit. Thereby, the current I5 and I6 flowing in the both of the transistors 201 and 203 become equal to each other. When the current I5 and I6 flowing in the both of the transistors 201 and 203 are expressed as follows, when the threshold voltage of the transistor 201 is Vth.

I5=I6=(VAA−Vth)/R5 [Expression 5],

Therefore, output current I6 of the second current generating circuit 200 changes in accordance with change of the magnitude of the operation voltage VAA.

The output circuit 300 adds the output current I3 from the first current generating circuit 100 and the output current I6 from the second current generating circuit 200, and generates a current I4 (=I3+I6).

This current I4 flows in the resistor 301 having a resistance value of R4 to cause a voltage drop of I4×R4. This voltage drop is output from the output terminal 11B as the output voltage VDC. As described above, the reference voltage generating circuit 1 of this embodiment generates an output voltage by the voltage drop of the I4, which is a sum of the current I3 with a temperature dependency, and the current I6 with a power-supply-voltage dependency.

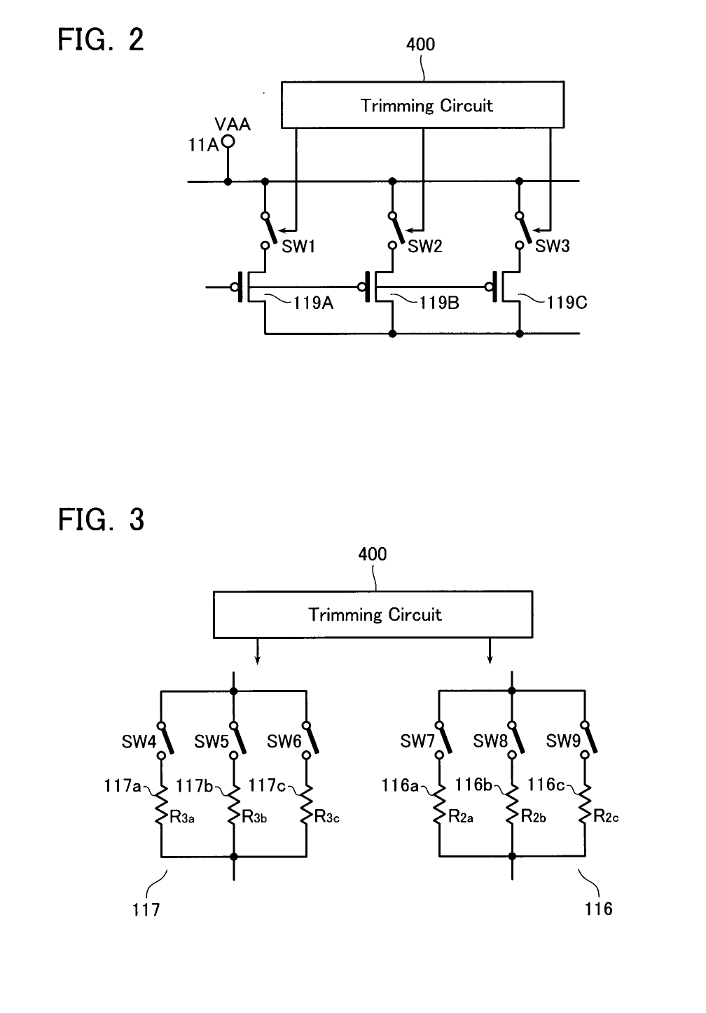

The current I3 and I6 may be controlled independent of the magnitude of the other. That is, the dependency of the output voltage VDC toward the temperature T, and the dependency over the power supply voltage VAA may be independently controllable, respectively. The structure for performing this control is explained with reference to FIG. 2 or 5.

Namely, in order to increase or decrease the dependency of the output voltage VDC toward temperature T in the circuit 1 of FIG. 1, the following measures (1) and (2) are effective.

(1) change the channel width W of the p-type MOS transistor 119 to increase or decrease the current I3

(2) increase or decrease the resistance value of R2 and R3 of the resistor 116 and resistor 117 at an equal rate to increase or decrease the current I2, then the current I3.

To realize (1), the p-type MOS transistor 119 may be configured as shown in FIG. 2. That is, a plurality of p-type MOS transistors (in FIG. 2, three) 119A, 119B, and 119C with different channel widths W connected in parallel are formed as the p-type MOS transistor 119. Each of the transistors 119A-C has switching elements SW1-SW3 between the operation voltage VAA and themselves. By selectively turning on either of the switching elements SW1-SW3 by a switching signal from a trimming circuit 400, the channel width W can be changed in a stepwise fashion.

Fuse elements may be used instead of the switching elements SW1-SW3 to choose either of the transistors 119A, 119B, and 119C. Moreover, it is needless to say that the concrete means is not limited to the example shown in FIG. 2, as far as the channel width W is variable.

In order to realize (2), for example, as shown in FIG. 3, a plurality of resistors 116 a-c and 117 a-c having incrementally-different resistance values may be connected in parallel as the resistor 116 and 117. The resistance values of R2 and R3 can be made to fluctuate in a stepwise fashion at an equal rate by selectively turning on the switching circuits SW4-SW9 by a switching signal from a trimming circuit 400.

Fuse elements may be used instead of the switching elements SW4-SW9 to choose the resistor 116 a-c or 117 a-c. Moreover, it is needless to say that the concrete means is not limited to the example shown in FIG. 3, as far as the resistance value may be made variable.

Moreover, in order to make the dependency of the output voltage VDC toward the operation voltage VAA in the circuit of FIG. 1, the following measures (3) and (4) are effective.

(3) change the channel width W of the p-type MOS transistor 203 to increase or decrease the current I6

(4) change the resistance value of the resistance 202 to increase or decrease the current I5, then the current I6

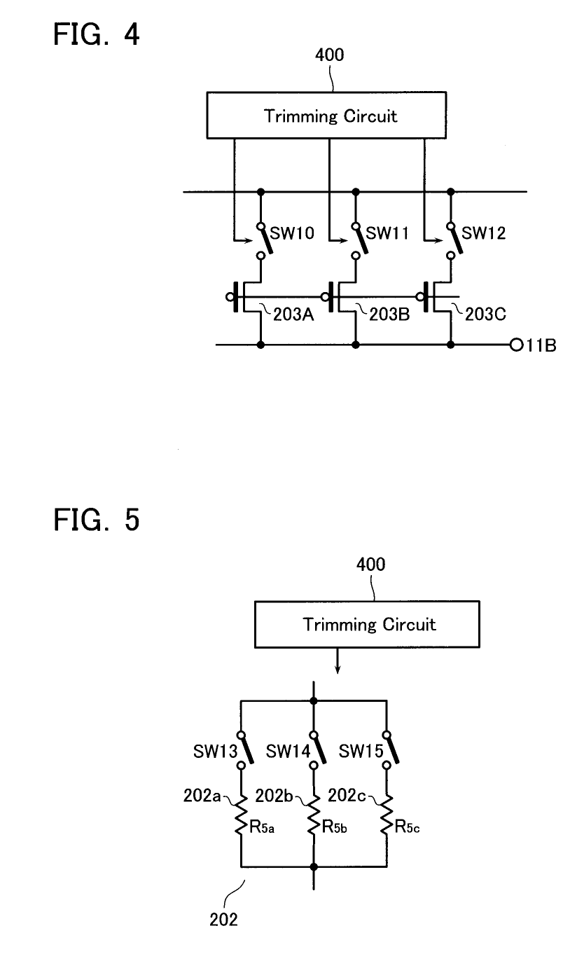

To realize (3), the p-type MOS transistor 203 can be configured as shown in FIG. 4. That is, a plurality of p-type MOS transistors (in FIG. 4, three) 203A, 203B, and 203C with different channel widths W may be formed connected in parallel as the p-type MOS transistor 203. Each of the transistors 203 A-C has the switching elements SW10-SW12 between the operation voltage VAA and themselves.

By selectively turning on either of the switching elements SW10-SW12 by a switching signal from a trimming circuit 400, the channel width W can be changed in a stepwise fashion. Similar to that of the case of FIG. 2, fuse elements may be used instead of switching elements.

Moreover, in order to realize (4), for example, as shown in FIG. 5, a plurality of resistors 202a-c having incrementally-different resistance values are connected in parallel as the resistor 202.

The resistance value of R5 can be increased or decreased in a stepwise fashion by selectively turning on the switching circuits SW13-SW15 by a switching signal from a trimming circuit 400. Similar to the case of FIG. 2, fuse elements may be used instead of switching elements.

### Second Embodiment

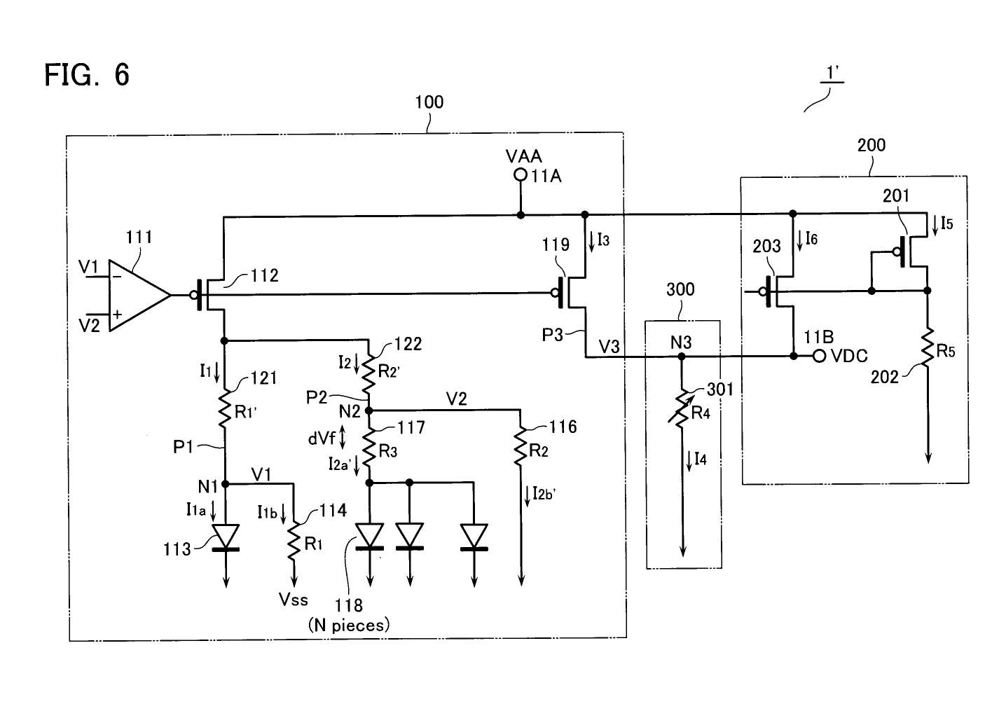

Next, the second embodiment of the present invention is explained with reference to FIG. 6. In FIG. 6, since the same reference numerals are used to denote the same components as FIG. 1, the detailed explanation thereof is omitted hereinbelow. The reference voltage generating circuit of this embodiment differs from the first embodiment in the following two points.

### (1) A resistor 121 (a resistance value of R1′, a fourth resistor element) is formed in the anode side of the diode 113 of the first current path P1.

### (2) A resistor 122 (a resistance value of R2′, the fifth resistor element) is formed a between the p-type MOS transistor 112 and the resistor 116 in the second current path P2.

In addition, the resistance values of R1′ and R2′ are made equal.

Moreover, the first current path P1 and the second current path P2 share the p-type MOS transistor 112. This embodiment differs from the first embodiment in that the p-type MOS transistor 115 is omitted.

Also in this embodiment, a control by the operational amplifier 111 is performed so that the voltage V1 and V2 becomes equal. Accordingly, currents flowing in the first and second current paths P1 and P2 also becomes equal. Since the p-type MOS transistor 115 is omitted in this embodiment, the circuit may be designed so that the output voltage VDC cannot be easily influenced by the variation in the threshold voltage of a transistor compared to the first enforcement.

As mentioned above, although the embodiments of the present invention have been explained, the present invention is not limited to these embodiments. Various changes, substitutions, additions, deletions and the like are possible without departing from the scope of the present invention. For example, in the case of a constant temperature, the first current generating circuit 100 may output a constant current irrespective of the power supply voltage. And when temperature changes, the output current may be changed according to this. Moreover, the second current generating circuit 200 is not restricted to what is shown in FIG. 1 or FIG. 6, either, as far as it outputs an output current that changes according to the changes in the operation voltage VAA.

What is claimed is:

1. A reference voltage generating circuit comprising:
a first current generating circuit generating first current that is constant irrespective of a power supply voltage when temperature is constant, while the magnitude of the first current changes, when temperature changes, in accordance with the change of temperature;
a second current generating circuit generating a second current depending on the power supply voltage;
an output circuit including a resistor element flowing a third current generated by adding the first current and the second current to output an output voltage produced by the voltage drop of the resistor element.

2. The reference voltage generating circuit according to claim 1, wherein
the first current generating circuit comprises at least a first current path, a second current path, and a third current path between a power supply voltage node where the power supply voltage is fed and a ground potential,
the first current path being formed by serial-connecting a first transistor and a first diode at a first node while parallel-connecting the first diode and a first resistor element,
the second current path being formed by serial-connecting a second transistor connected in a current mirror connection manner with the first transistor and a second resistor element at a second node while serial-connecting a third resistor element and a second diode in parallel with the second resistor element,
the third current path comprising a third transistor in a current mirror connection manner with the first and second transistors,
and the reference voltage generating circuit further comprises a control circuit comparing the voltages of the first node and the second node and applying a comparison signal to control terminals of the first, second and third transistor to control the currents of the first, second and third current path.

3. The reference voltage generating circuit according to claim 2, wherein the first, second and third transistor have the same size.

4. The reference voltage generating circuit according to claim 2, wherein
the second current generating circuit comprises:
a fourth transistor having one end given the power supply voltage and diode-connected;
the fifth transistor having one end given the power supply voltage, the other end connected to the output circuit, and a gate commonly connected with the fourth transistor; and
a resistor element serially-connected to the fourth transistor.

5. The reference voltage generating circuit according to claim 2, wherein
the second diode comprises a plurality of diode elements.

6. The reference voltage generating circuit according to claim 1, wherein
the first current generating circuit comprises at least a first current path, a second current path, and a third current path between a power supply voltage node where the power supply voltage is fed and a ground potential,
the first current path being formed by serial-connecting a first transistor, a fourth resistor element and a first diode while parallel-connecting the first diode and a first resistor element,
the second current path being formed by serial-connecting the first transistor, a fifth resistor element and a second resistor element while serial-connecting a third resistor element and a second diode in parallel with the second resistor element,
the third current path comprising a second transistor in a current mirror connection manner with the first transistor,
and the reference voltage generating circuit further comprising a control circuit comparing a voltage of a first node between the fourth resistor element and the first diode with that of a second node between the fifth resistor element and the third resistor element, and applying a comparison signal to control terminals of the first and second transistor to control the currents of the first, second and third current path.

7. The reference voltage generating circuit according to claim 6, wherein
the first, second and third transistors have the same size.

8. The reference voltage generating circuit according to claim 6, wherein
the second current generating circuit comprises:
a fourth transistor having one end given the power supply voltage and diode-connected;
the fifth transistor having one end given the power supply voltage, the other end connected to the output circuit, and a gate commonly connected with a gate of the fourth transistor; and
a resistor element serially-connected to the fourth transistor.

9. The reference voltage generating circuit according to claim 6, wherein the second diode comprises a plurality of diode elements.

10. The reference voltage generating circuit according to claim 1, wherein
the power supply voltage is a voltage supplied to a sense amplifier of a ferroelectric random-access memory, or a plate voltage applied between both electrodes of cell capacitors in the ferroelectric random-access memory, and
the output voltage is applied between both electrodes of a dummy capacitor generating a reference voltage of the ferroelectric random-access memory.

11. The reference voltage generating circuit according to claim 2, wherein
the resistance of the second resistor element and the third resistor element may be adjusted to vary the temperature characteristic of the first current.

12. The reference voltage generating circuit according to claim 6, wherein
the resistance of the second resistor element and the resistance of the third resistor element may be adjusted to vary the temperature characteristic of the first current.
